(19) United States
(12) Patent Application Publication
(10) Pub. No.: US 2026/0096417 A1
(43) Pub. Date: Apr. 2, 2026

(54) SEMICONDUCTOR DIE AND METHOD OF MANUFACTURING THE SAME

(71) Applicant: Infineon Technologies AG, Neubiberg (DE)

(72) Inventors: Taisiia Romanova, Villach (AT); Dethard Peters, Höchstadt (DE); Markus Beninger-Bina, Aying (DE); Sascha Baier, Neubiberg (DE); Christian Krenn, Viktring (AT)

(21) Appl. No.: 19/327,331

(22) Filed: Sep. 12, 2025

(30) Foreign Application Priority Data
Sep. 27, 2024 (DE) 102024209378.5

(51) Int. Cl. H01L 23/528; H01L 21/768; H01L 23/522

(52) U.S. Cl. CPC H10W 20/427; H10W 20/033; H10W 20/088; H10W 20/089; H10W 20/42; H10W 20/43; H10W 20/435

(57) ABSTRACT

The disclosure relates to a semiconductor die that includes: a semiconductor body; an insulating layer; and a metallization. A conductor line is formed in the metallization and arranged outside an active area of the semiconductor die. A first contact opening is formed in the insulating layer below the conductor line. The conductor line is electrically connected to the semiconductor body in a first contact area in the first contact opening. The first contact opening is divided along a length extension of the conductor line into a plurality of first contact opening sections. The first contact area is provided with a respective first interruption between neighboring first contact opening sections.

### TECHNICAL FIELD

The present disclosure relates to a semiconductor die comprising a semiconductor body.

### BACKGROUND

In embodiments of this application, the semiconductor body is made of silicon carbide (SiC) which has a comparably wide band gap, e.g. compared to silicon. This can for instance be of interest for power semiconductor devices in high voltage and/or high current applications. In the semiconductor body, a device structure with a load terminal or terminals can be formed, for example a transistor structure having a source terminal and a drain terminal. For a wiring and contacting of the device structure, a metallization can be formed above the semiconductor body.

### SUMMARY

Examples of the present application are directed at an advantageous semiconductor die.

The semiconductor die may comprise a semiconductor body, an insulating layer above a first side of the semiconductor body, and a metallization above the insulating layer. In the metallization, a conductor line may be formed and arranged outside an active area of the die. Through a first contact opening formed in the insulating layer below, the conductor line is connected to the semiconductor body, e.g. to an entity formed in the semiconductor body or to the semiconductor body itself. In detail, the electrical contact may be formed via a first contact area in the first contact opening. In an embodiment, the first contact opening is divided along a length extension of the conductor line into a plurality of first contact opening sections, the insulating layer being for instance uninterrupted between neighboring first contact opening sections. Vice versa, the first contact area may respectively be interrupted between neighboring first contact opening sections, i.e. be provided with a respective first interruption.

In other words, the first contact area below the conductor line does, for instance, not extend continuously but with first interruptions, e.g. in a dashed pattern (see in detail below.). The interruption(s) can for example have an advantage in manufacturing, e.g. with respect to a structuring of the metallization. The metallization or a sublayer of the metallization can for instance be structured by a lift-off process, i.e. be deposited onto a structured mask in combination with a subsequent removal of the mask. This may be improved when a small undercut is formed in the insulating layer below the mask, e.g. a small underetch at a lateral edge of the insulating layer, which otherwise lies basically flush with a respective lateral edge of the mask, see FIGS. 4a-f for illustration. The segmentation of the contact opening may improve the undercut formation, e.g. in comparison to a continuous (uninterrupted) contact opening. The segmentation or interruption can for instance allow for a better attack of a solvent to lift off the mask.

Further embodiments and features are provided in the claims and throughout this disclosure. Therein, the individual features shall be disclosed independently of a specific claim category and/or embodiment. The disclosure relates to apparatus and device aspects, but also to method and use aspects. If, for instance, a die manufactured in a specific way is described, this is also a disclosure of a respective manufacturing process, and vice versa. In general words, an approach of this application is to divide an opening in the insulating layer into a plurality of opening sections, e.g. a contact opening below a conductor line or pad.

As discussed above, the conductor line or pad is arranged outside an active area, for instance in an edge termination area between the active area and a lateral edge of the die. In the active area, a device structure may be formed in the semiconductor body. The semiconductor body may be made of silicon carbide (SiC), possible alternatives being, for example, silicon (Si) or gallium nitride (GaN) or aluminum oxide (Al₂O₃). The device structure can, for instance, comprise a first load terminal arranged at the first side of the semiconductor body. Additionally, it may comprise a second load terminal, e.g. at a vertically opposite second side of the semiconductor body. The device structure can for instance be a FET having a source terminal/region and a drain terminal/region in the semiconductor body, e.g. the source region at the first side of the semiconductor body and the drain region at the second side thereof.

In addition to the source region and the drain region, the device may comprise a body region to which a gate electrode capacitively couples. Additionally, a drift region may be arranged between the body region and the drain region, e.g. made of the same doping type but with a lower concentration than the drain region. The source region and drain region and, if present, drift region may be made of a first doping type, the body region made of a second doping type. In an embodiment, the first doping type is n-type and the second doping type is p-type.

In general, the respective contact area, via which the metallization is connected to the semiconductor body, may be formed by a separate contact plug below the metallization. In an embodiment, however, the metallization itself forms the respective contact area, e.g. extends down to the semiconductor body in the respective contact opening. In detail, the respective contact area may be formed between a lowermost layer of the metallization, e.g. sputter-deposited layer, and the semiconductor body (i.e. where the lowermost metallization layer touches the semiconductor body). To improve the electrical contact, a highly doped contact region may be formed in the semiconductor body below the conductor line. In general, the highly doped contact region in the semiconductor body may be provided with interruptions as well, e.g. coinciding with the interruptions in the contact area. In an embodiment, however, the highly doped contact region extends uninterrupted, e.g. as a continuous line below the conductor line.

As discussed in further detail below, the conductor line can for instance form or be part of a runner, which extends aside and along the active area. It may extend along one or a plurality of the lateral edges of the die, e.g. have an L- or U-shape, or form a closed line around the active area. Independently of these details, it can for instance be a gate runner or a source runner of the device.

In an embodiment, a respective first contact opening section below the conductor line has a length of at least 0.5 μm and/or at most 50 μm. Further lower limits can, for instance, be at least 0.7 μm, 0.8 μm, 0.9 μm, 1 μm, 1.1 μm or 1.2 μm, though larger lower limits are conceivable as well, e.g. at least 2 μm. Further upper limits may be 20 μm, 10 μm or 5 μm. Independently of a specific value, the length may be respectively taken along the length extension of the conductor line, e.g. along a center line of the first contact opening as seen in a vertical top view. In detail, the length may be taken at a bottom of the respective contact opening section (where the contact area is formed).

In an embodiment, a respective interruption of the contact area or, vice versa, respective uninterrupted portion of the insulating layer, has a length of at least 0.5 μm and/or at most 50 μm. Further lower limits may be, for instance, at least 0.7 μm, 0.8 μm, 0.9 μm, 1 μm, 1.1 μm or 1.2 μm, though larger lower limits are conceivable as well, e.g. at least 2 μm. Further upper limits can for instance be most 20 μm, 10 μm or 5 μm. Again, the length may be taken along the length extension of the conductor line, e.g. along a center line of the first contact opening as seen in a vertical top view.

In an embodiment, the first contact opening sections form a dashed pattern along at least a portion of the conductor line. Therein, the “dashed pattern” may be characterized by the number of contact opening sections provided per unit length, e.g. at least five contact opening sections along a conductor line length of 100 μm. Therein, the portion of the conductor line, where the dashed pattern is provided, may extend further, e.g. have a length of several hundred micrometers or even extend in a millimeter range.

Further lower limits for the number of first contact opening sections per unit length of 100 μm can for instance be at least 10, 15 or 20 first contact opening sections. Possible upper limits can for instance be at most 100, 80, 60 or 50 first contact opening sections per 100 μm unit length. Independently of a specific number, the “dashed pattern” may be irregular, i.e. be provided with a varying length of the contact opening sections and/or varying distances in between the contact opening sections. Alternatively, it may be regular, the contact opening sections having respectively the same length and being arranged with respectively the same distance in between.

In an embodiment, the conductor line extends along a lateral edge of the die, wherein the dashed pattern is provided along at least 25% of a total length which the conductor line has along the respective lateral edge. As seen in a vertical top view, the conductor line may extend in parallel to the lateral edge, wherein the total length may be taken as far as this parallel extension goes, e.g. neglecting a curved portion in a corner. In other words, the total length can for instance be taken as far as the conductor line extends as a straight line. Independently of these details, the dashed pattern, in this embodiment, may extend over a portion (≥25%) of the total length or over the entire total length (100%).

In an embodiment, the conductor line has a curved shape in a corner of the semiconductor die, i.e. in a transition between two adjacent lateral edges of the die. The dashed pattern may be provided along at least a segment of the curved shape, e.g. over a portion of the curved shape or over the entire curved shape. Due to the curved shape in the corner, an area between the conductor line and the lateral edges of the die may be larger, wherein for instance a respective area of a mask in a lift-off process may be larger as well. In this respect, the underetch discussed above, i.e. possible solvent attack in the lift-off process, may be advantageous.

In an embodiment, the conductor line is or belongs to a runner, wherein a second contact opening is formed below the runner. The second contact opening is arranged with a lateral offset to the first contact opening in a transverse direction, i.e. perpendicular to a length extension of the runner. The contact openings below the runner can for instance be arranged in parallel to each other, their respective center lines having for instance a constant distance to each other, as seen in a vertical top view. As discussed above, the runner may for instance be a gate runner or a source runner, i.e. be connected to a gate terminal, e.g. gate electrode, or to a source region of a device structure formed in the active area.

Generally, the segmentation of the (first) contact opening in into a plurality of (first) contact opening sections relates to the length direction of the runner. Vice versa, the segmentation referenced by the different contact openings (first, second, and so on) relates to the transverse direction, which lies perpendicular to the length direction.

In other words, a contact region below the runner, which has a certain width in the transverse direction, is divided into a plurality of contact openings arranged aside each other (and separated from each other by a respective portion of the insulating layer). As discussed above for the segmentation of the first contact opening along the length direction, the segmentation in the transverse direction may improve an undercut formation (and a lift-off process), e.g. in comparison to a contact opening extending uninterrupted over the entire width of the runner. Despite of the segmentation into a plurality of contact openings, the conductor line of the runner via the different contact opening sections may be electrically connected to the same entity in the semiconductor body, e.g. doped region (source region) or polysilicon structure (gate electrode).

In an embodiment, the first contact opening, which is provided with the segmented first contact area, e.g. dashed pattern, is a laterally innermost or laterally outermost contact opening below the runner. The laterally innermost contact opening may be arranged closer to the active area than the other contact openings below the runner, whereas the outermost contact opening may be arranged closer to the lateral edges than the other contact openings of the runner. Laterally inside and/or outside of the runner, a respective area without a metallization may be arranged, so that a mask used in a lift-off process can have a comparably large area there (and the segmentation is advantageous, see above).

In an embodiment, the second contact opening forms a second contact area to the semiconductor body, which is segmented as well. In other words, a second contact opening below the conductor line is divided along the length extension of the conductor line into a plurality of second contact opening sections, as discussed for the first contact opening above. All embodiments described above for the first contact opening and the first contact area shall also be disclosed with respect to the second contact opening/contact area. By way of example, the second contact opening may form a dashed pattern as well. The first and second contact opening may for instance be the inner and outermost contact openings of the runner with respect to the transverse direction. In general, also a further contact opening, which may be arranged laterally between the first and the second contact opening with respect to the transverse direction, may be provided with a dashed pattern. By way of example, all contact openings arranged below the conductor line may be provided with a dashed pattern along the length extension.

In an embodiment, at least one additional contact opening is formed below the runner, which is arranged laterally between the first and the second contact opening with respect to the transverse direction. The at least one additional contact opening connects the conductor line to the semiconductor body via a respective contact area below. Therein, the at least one additional contact area below the runner may be continuous along the length direction of the runner, i.e. be not interrupted/segmented. In other words, the at least one additional contact area/contact opening below the runner may extend as a continuous line as seen in a vertical top view. In combination with the first and/or second contact opening forming a segmented contact area in the length direction, the one or plurality of additional contact opening with a respective continuous contact area along the length direction can for instance allow for an optimization of both, the lift-off and of the electrical contact properties.

In an embodiment, a width of a respective contact opening, e.g. first or second or additional contact opening, and/or a distance between neighboring contact openings below the runner is at least 0.5 μm and/or at most 3 μm. The width and distance are respectively taken in the transverse direction.

As discussed above, a device, e.g. transistor device, can be formed in the active area. In detail, such a device may comprise a plurality of device cells, which are arranged consecutive with a cell pitch in the active area. The device cells can for instance be electrically connected in parallel and/or be arranged with a translational symmetry with respect to each other (respectively displaced by the cell pitch).

Independently of these details, a distance taken in the transverse direction between neighboring contact openings below the runner may, in an embodiment, differ by not more than +/−80% from the cell pitch in the active area. In other words, the distance between neighboring contact openings may be at most 80% smaller or larger than the cell pitch. Further upper limits can for instance be 60%, 50%, 40%, 30% or 20%, the distance may also be equal to the cell pitch. Adapting the dimensions of the runner to those in the active area can for instance allow for reducing differences in the lift off behavior.

In an embodiment, a plurality of device contact openings in the insulating layer are formed in the active area, wherein each device contact opening belongs to a respective device cell. A respective device contact opening may form an electrical contact to an element of the respective device cell, e.g. to a source and/or body region. The device contact openings in the active area can have their length extension in a first lateral direction, the device cells having their translational symmetry with respect to a second lateral direction perpendicular thereto.

In an embodiment, a width of a respective contact opening of the runner differs by not more than +/−80% from a device contact opening width in the active area, wherein the contact opening width is respectively taken in the transverse direction/perpendicularly to the length extension. In other words, a contact opening width in the runner is at most 80% smaller or larger than a contact opening width in the active area, wherein further upper limits may be 60%, 50%, 40%, 30% or 20% (the width in the runner may also be equal to the width in the active area).

In an embodiment, a method of manufacturing a semiconductor die comprises: forming an insulating layer above a first side of a semiconductor body; ii) forming a mask on the insulating layer, the mask defining an opening which is arranged outside an active area of the semiconductor die; and divided along a length extension into a plurality of opening sections; iii) etching the opening defined by the mask into the insulating layer; iv) depositing at least one sublayer of a metallization onto the mask and into the opening etched into the insulating layer; v) removing the mask from the insulating layer.

The mask in step ii) may for instance be formed by depositing and structuring a photoresist layer; the mask can for instance be an organic layer. For example, the mask may define further openings in the active area (as well as outside the active area). The mask defining the openings in the insulating layer is opened in step iii), i.e. where the contact to the semiconductor body is formed.

After the opening for the contact formation has been etched into the insulating layer in step iii), at least one sublayer of the metallization is deposited in step iv), wherein the mask is still in place. In other words, the at least one sublayer of the metallization may contact the semiconductor body where the insulating layer is opened, and it may cover the mask aside. When the mask is removed in step v), that part of the sublayer, which contacts the semiconductor body in the openings, remains, whereas the portion of the sublayer aside is removed together with the mask.

The at least one sublayer of the metallization can for instance be a sputter deposited metal layer, e.g. a metal layer comprising nickel and/or aluminum. In a later processing, the sublayer may serve as a seed layer, e.g. for a bath-deposition of a further layer or layer stack, for instance copper layer(s). Independently of these details, the at least one sublayer deposited in step iv) can for instance have a thickness of at least 30 nm, e.g. at least 40 nm, and/or at most 90 nm, e.g. at most 70 nm.

In an embodiment, step iii) comprises an isotropic etch step and a subsequent anisotropic etch step. The anisotropic etch step may form the contact opening, wherein the previous isotropic etch step may cause an undercut below the mask, as discussed above. The anisotropic etch step, but also the isotropic etch step, may for instance be done by dry etching.

In an embodiment, step v) comprises an application of a solvent onto the mask and the at least one sublayer. This solvent, which dissolves or detaches the mask, may attack the mask better where the undercut is formed, because the at least one sublayer may be ruptured there. Since the segmented contact area/opening may improve the undercut formation, it can also improve this lift-off process.

As mentioned above, any feature discussed with respect to the die, shall also be disclosed with respect to the manufacturing method, and vice versa.

### BRIEF DESCRIPTION OF THE DRAWINGS

Below, the semiconductor die and method of manufacturing are explained in further detail by means of exemplary embodiments. Therein, the individual features can also be relevant in a different combination.

FIG. 1 shows a cross-sectional view of a conductor line on a semiconductor body;

FIG. 2 illustrates contact openings below a runner at a corner of a semiconductor die in a vertical top view;

FIG. 3 shows a vertical cross-section through a runner;

FIGS. 4 a-f illustrate different steps of forming a contact opening and a sublayer of a metallization in the contact opening;

FIG. 5 illustrates manufacturing steps in a flow diagram; and

FIG. 6 illustrates a device, which can be formed in an active area of the die, in a vertical cross-section.

### DETAILED DESCRIPTION

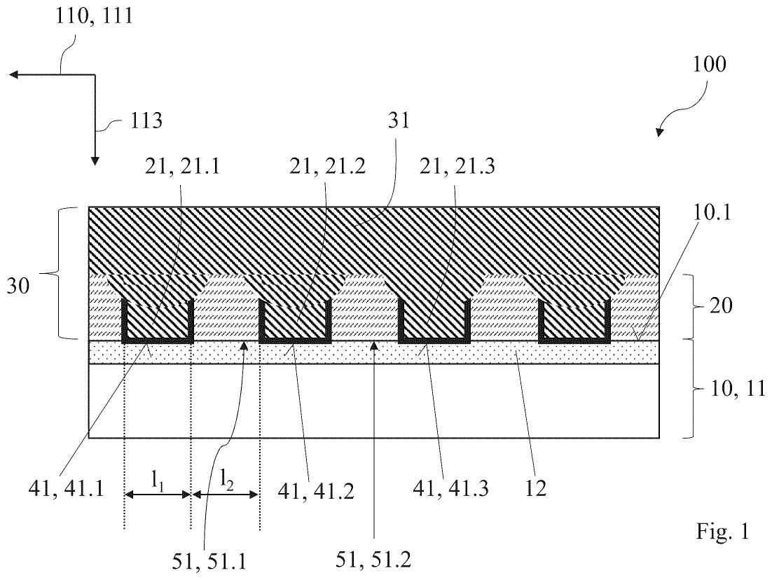

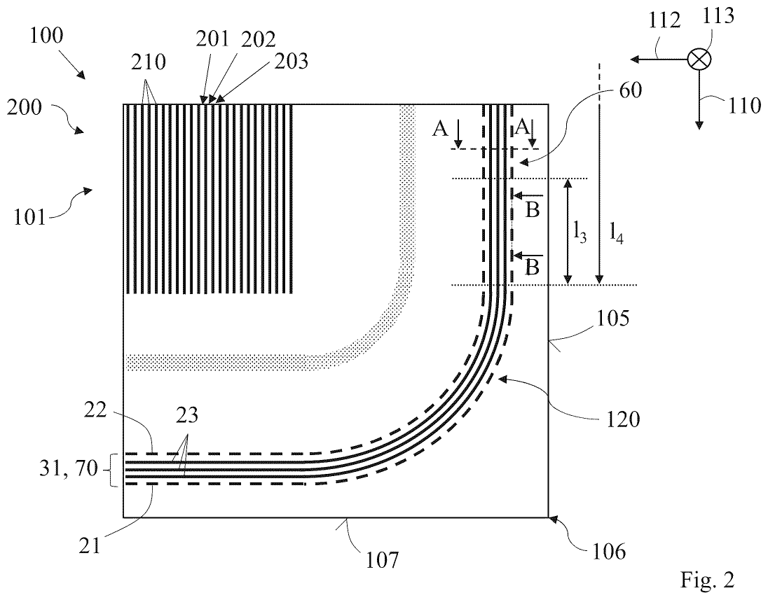

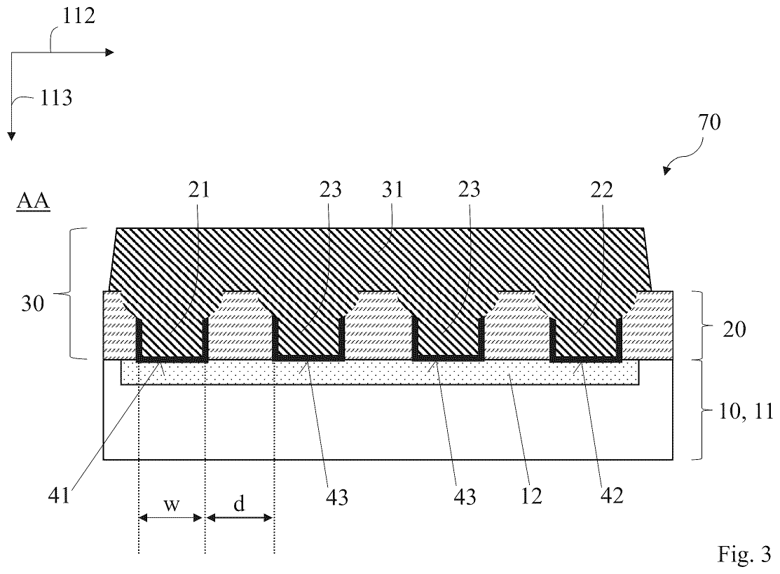

FIG. 1 shows a vertical cross-section of a portion of a semiconductor die 100 and illustrates a semiconductor body 10, which is a silicon carbide (SiC) semiconductor body 11 in the example shown. On a first side 10.1 of the semiconductor body 10, an insulating layer 20 is arranged, which can for instance be a silicon oxide layer or layer stack, e.g. comprising a PSG or a BPSG layer. A metallization 30 is formed on the insulating layer 20, wherein the cross-section of FIG. 1 shows a conductor line 31 formed in the metallization 30. The sectional plane lies parallel to a length direction 111 and to a vertical direction 113. In other words, the sectional view of FIG. 1 goes along a length extension 110 of the conductor line 31 (see BB in FIG. 2).

The conductor line 31 is electrically connected to the semiconductor body 10 through a first contact opening 21 etched into the insulating layer 20. Therein, as illustrated in FIG. 1, the first contact opening 21 does not extend continuously along the length extension 110, but is divided into a plurality of first contact opening sections 21.1-21.3. Consequently, a first contact area 41, via which the conductor line 31 is electrically connected to the semiconductor body 10, is provided with first interruptions 51, i.e. a respective first interruption 51.1, 51.2 between neighboring first contact opening sections 21.1-21.3. Vice versa, the first contact area 41 is segmented into first contact area sections 41.1-41.3.

Taken along the length extension 110, i.e. in the length direction 111, a respective first contact opening section 21.1-21.3 may have a length 11 of 0.5 μm-50 μm, e.g. around 3 μm in the example shown. A respective interruption 51.1, 51.2 of the contact area 41 may have a length 12 of 0.5 μm-50 μm, e.g. around 3 μm in the example shown.

FIG. 2 shows a portion of the semiconductor die 100 in a vertical top view, i.e. as seen in the vertical direction 113. The portion shown is located at a corner 106 of the die 100, where two the lateral edges 105, 107 of the die 100 lie adjacent to each other. As indicated on the lower left, the conductor line forms a runner 70. Below the runner 70, a second contact opening 22 and at least one additional contact opening 23 are formed, see in detail below.

The first and second contact opening 21,22 are illustrated as hatched lines, which illustrates interruption/segmentation in the length direction. The interruptions, i.e. contact opening sections (see FIG. 1), form a dashed pattern 60. Therein, for instance 5-100 contact opening sections may be provided over a conductor line length 13 of 100 μm (“unit length”), i.e. around 8 contact opening sections in the example shown.

With reference to a total length 14, which the conductor line 31 has along the lateral edge 105, the dashed pattern 60 may extend over at least 25% of the total length 14, i.e. over the entire total length 14 in the example shown. In the corner 106, the conductor line 31 has a curved shape 120, wherein the dashed pattern 60 is also provided over the curved shape 120 (which applies also for the second contact opening 22).

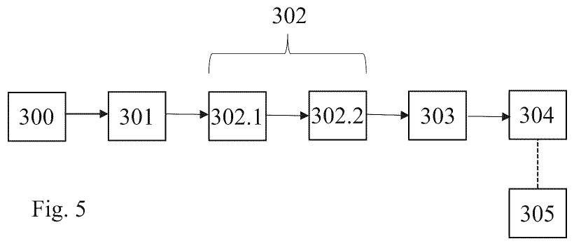

FIG. 2 also illustrates an active area 101 of the die 100. In the active area 101, a semiconductor transistor device 200, which comprises a plurality of device cells 201-203, is formed, see FIG. 5 for further details. To the device cells 201-203, a respective device contact opening 210 belongs, wherein these device contact openings 210, in the example shown, respectively have a width comparable to a width of a respective contact opening 21-23 of the runner 70.

FIG. 3 illustrates the width w in a vertical cross-section through the runner 70, see the sectional plane AA as referenced in FIG. 2. Generally, in this disclosure, the like reference numerals indicate like elements or elements having the like function, and reference is made to the description of the respectively other figures as well. With respect to the transverse direction 112, the runner 70 is provided as one single conductor line, though separate contact areas 41-43 are formed below and are arranged at a distance d to each other, which is comparable to a distance between the device contact openings in the active area.

As discussed above, the second contact area 42 is segmented as well, i.e. like the first contact area 41. At least one additional contact opening 23, i.e. two additional contact openings 23 in the example shown (wherein other numbers are possible as well, as shown in FIG. 2), is arranged between the first and the second contact opening 21, 22. There, the contact areas 43 extend uninterrupted, respectively, as also indicated by the continuous lines in FIG. 2.

FIG. 3 also illustrates, like FIG. 1, a highly doped region 12 formed in the semiconductor body 10, which may improve the electrical contact to the semiconductor body 10. As illustrated in FIG. 3, the high doped region 12 extends uninterrupted between the contact openings 21-23, which applies also for its extension in the length direction 111 below the first and second contact opening 21, 22 (see FIG. 1 for illustration).

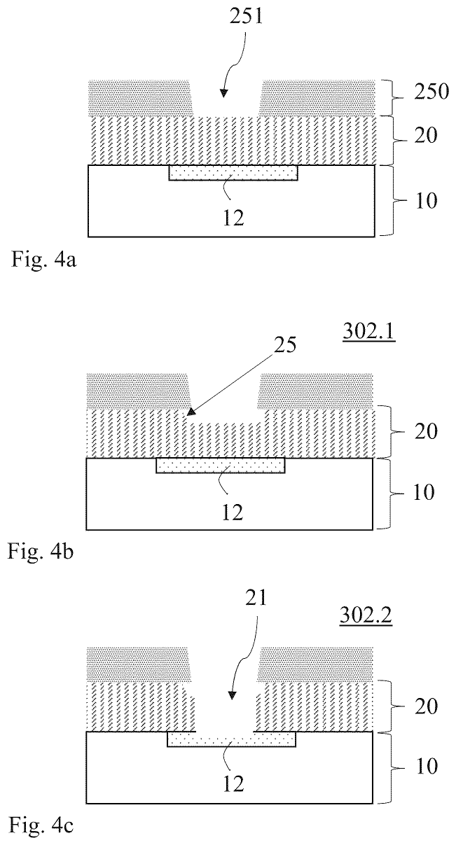

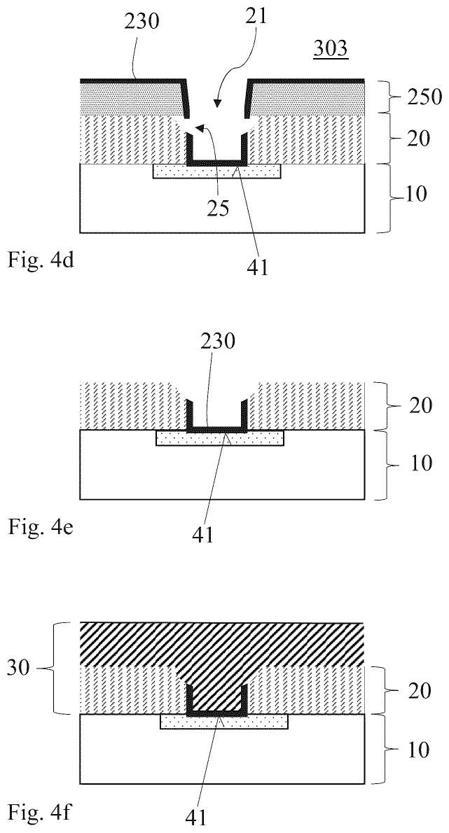

FIGS. 4a-f illustrate some manufacturing steps for a contact opening formation and subsequent metallization or metallization sublayer deposition. In FIG. 4a, the high doped region 12 has been formed in the semiconductor body 10, and the insulating layer 20 has been deposited onto the semiconductor body 10. Further, a mask 250 has been formed on the insulating layer 20. The mask 250 has been structured, i.e. defines an opening 251 for a subsequent etch step.

FIG. 4b illustrates an isotropic etch step 302.1, in which an undercut 25 is etched into the insulating layer 20. In a subsequent anisotropic etch step 302.2, as illustrated in FIG. 4c, the entire contact opening 21 is etched through the insulating layer 20.

FIG. 4d illustrates a subsequent deposition 303 of a sublayer 230, which is the lowermost layer of the metallization. In the opening 21, the sublayer 230 forms the contact area 41 to the semiconductor body 10. Laterally aside, it is deposited onto the mask 250, to be removed together with the mask 250 in a lift-off process. The undercut 25, as illustrated in FIG. 4d, supports a local rupture of the sublayer 230, allowing for an improved attack of a solvent to the resist of the mask 250.

FIG. 4e illustrates a situation after a removal of the mask, the sublayer 230 remains at the bottom of the contact opening 21. The entire metallization 30 is formed in subsequent steps, see FIG. 4f for illustration.

FIG. 5 summarizes some manufacturing steps in a flow diagram. After forming (step 300) the insulating layer, the mask may be formed (step 301) on the insulating layer. Then, the opening may be etched (step 302) into the insulating layer, i.e. in an isotropic and a subsequent anisotropic etch step (step 302.1), (step 302.2); see above. Then, the sublayer may be deposited (step 303) before the mask is removed (step 304), e.g. by applying (step 305) a solvent.

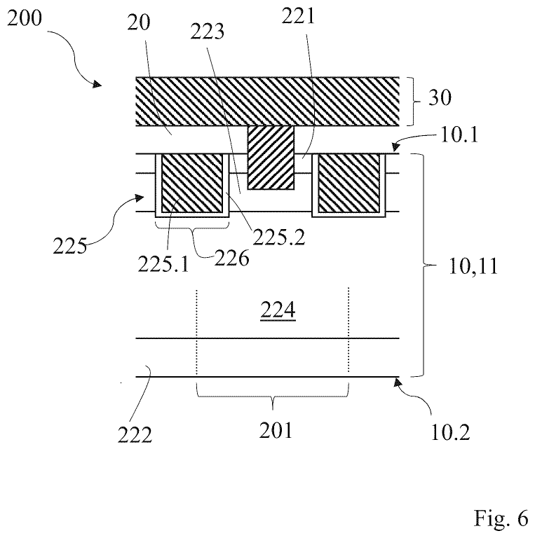

FIG. 6 shows a semiconductor transistor device 200 with a device cell 201. At the first side 10.1 of the semiconductor body 10, a source region 221 is arranged, wherein a drain region 222 is formed at the vertically opposite second side 10.2 of the semiconductor body 10. In addition, the device 200 comprises a body region 223, wherein a gate region 225 is arranged laterally aside in a gate trench 226. It comprises a gate electrode 225.1 and a gate dielectric 225.2, via which the gate electrode 225.1 capacitively couples to the body region 223. By applying a voltage to the gate electrode 225.1, a vertical current flow through the device 200 can be controlled.

The device 200 shown additionally comprises a drift region 224, which is made of the same doping type but with a lower doping concentration compared to the drain region 222. In the example shown, the source region 221, the drain region 222, and the drift region 224 are n-doped, wherein the body region 223 is p-doped.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor die, comprising:
a semiconductor body;
an insulating layer above a first side of the semiconductor body;
a metallization above the insulating layer;
wherein a conductor line is formed in the metallization and arranged outside an active area of the semiconductor die,
wherein a first contact opening is formed in the insulating layer below the conductor line,
wherein the conductor line is electrically connected to the semiconductor body in a first contact area in the contact opening,
wherein the first contact opening is divided along a length extension of the conductor line into a plurality of first contact opening sections,
wherein the first contact area is provided with a respective first interruption between neighboring first contact opening sections.

2. The semiconductor die of claim 1, wherein a respective first contact opening section has, taken along the length extension of the conductor line, a length of at least 0.5 μm and/or at most 50 μm.

3. The semiconductor die of claim 1, wherein a respective first interruption of the first contact area has, taken along the length extension of the conductor line, a length of at least 0.5 μm and/or at most 50 μm.

4. The semiconductor die of claim 1, wherein the first contact opening sections form a dashed pattern along at least a portion of the conductor line, and wherein in the dashed pattern at least five first contact opening sections, with a respective first interruption of the contact area between neighboring first contact opening sections, are provided along a conductor line length of 100 μm.

5. The semiconductor die of claim 4, wherein the conductor line extends along a lateral edge of the semiconductor die, and wherein referring to a total length of the conductor line along the lateral edge, the dashed pattern is provided along at least 25% of the total length.

6. The semiconductor die of claim 4, wherein the conductor line has a curved shape in a corner of the semiconductor die, and wherein the dashed pattern is provided along at least a segment of the curved shape.

7. The semiconductor die of claim 1, wherein the conductor line is or belongs to a runner which extends along the active area, wherein a second contact opening is formed in the insulating layer below the runner, and wherein the second contact opening is offset laterally to the first contact opening in a transverse direction perpendicular to the length extension of the runner.

8. The semiconductor die of claim 7, wherein the first contact opening is a laterally innermost or outermost contact opening of the runner.

9. The semiconductor die of claim 8, wherein a third contact opening is formed in the insulating layer below the runner, wherein the third contact opening is arranged laterally between the first contact opening and the second contact opening, wherein the runner is electrically connected to the semiconductor body via a third contact area in the third contact opening, and wherein the third contact area is continuous along a length extension of the runner.

10. The semiconductor die of claim 7, wherein the runner is electrically connected to the semiconductor body via a second contact area in the second contact opening, wherein the second contact opening is divided along a length extension of the conductor line into a plurality of second contact opening sections, and wherein the second contact area is provided with a respective second interruption between neighboring second contact opening sections.

11. The semiconductor die of claim 10, wherein a third contact opening is formed in the insulating layer below the runner, wherein the third contact opening is arranged laterally between the first contact opening and the second contact opening, wherein the runner is electrically connected to the semiconductor body via a third contact area in the third contact opening, and wherein the third contact area is continuous along a length extension of the runner.

12. The semiconductor die of claim 7, wherein a width of a respective contact opening and/or a distance between neighboring contact openings below the runner, each measured in the transverse direction, is at least 0.5 μm and/or at most 3 μm.

13. The semiconductor die of claim 7, wherein a plurality of device cells is arranged consecutively with a cell pitch in the active area, and wherein a distance between neighboring contact openings below the runner differs by not more than +/−80% from the cell pitch in the active area.

14. The semiconductor die of claim 13, wherein a plurality of device contact openings in the insulating layer is formed in the active area, wherein each device contact opening belongs to a respective device cell, and wherein a width of a respective contact opening below the runner differs by not more than +/−80% from a device contact opening width in the active area.

15. A method of manufacturing a semiconductor die, the method comprising:
forming an insulating layer above a first side of a semiconductor body;
forming a mask on the insulating layer, the mask defining an opening which is arranged outside an active area of the semiconductor die and divided along a length extension into a plurality of opening sections;
etching the opening defined by the mask into the insulating layer;
depositing at least one sublayer of a metallization onto the mask and into the opening etched into the insulating layer; and
removing the mask from the insulating layer.

16. The method of claim 15, wherein etching the opening defined by the mask into the insulating layer comprises:
an isotropic etch step; and
a subsequent anisotropic etch step.

17. The method of claim 15, wherein removing the mask from the insulating layer comprises:
applying a solvent onto the mask and the at least one sublayer.

18. The method of claim 15, wherein a conductor line is formed in the metallization and arranged outside the active area of the semiconductor die, wherein the opening etched into the insulating layer is a first contact opening formed below the conductor line, wherein the conductor line is electrically connected to the semiconductor body in a first contact area in the contact opening, and wherein the at least one sublayer deposited onto the mask and into the opening etched into the insulating layer forms the first contact area to the semiconductor body.
